(19) United States
(12) Patent Application Publication
(10) Pub. No.: US 2024/0178232 A1
(43) Pub. Date: May 30, 2024

(54) THIN-FILM TRANSISTOR SUBSTRATE

(71) Applicant: Xiamen Tianma Display Technology Co., Ltd., Xiamen (CN)

(72) Inventor: Kazushige TAKECHI, Kawasaki (JP)

(21) Appl. No.: 18/519,769

(22) Filed: Nov. 27, 2023

(30) Foreign Application Priority Data
Nov. 28, 2022 (JP) 2022-189398
Aug. 29, 2023 (JP) 2023-138878

(51) Int. Cl. H01L 27/12

(52) U.S. Cl. CPC H01L 27/1218; H01L 27/1225; H01L 27/1251; H01L 27/1255

(57) ABSTRACT

A thin-film transistor substrate includes a first insulating film, a second insulating film located upper than the first insulating film, a first thin-film transistor, a second thin-film transistor, and a capacitive element. The first thin-film transistor includes a top-gate electrode and a first semiconductor region located above the first insulating film. The second thin-film transistor includes a second semiconductor region located above the second insulating film. The capacitive element includes at least a part of the top-gate electrode and a first low-resistive semiconductor region of the same semiconductor layer that includes the second semiconductor region, the first low-resistive semiconductor region overlapping at least a part of the top-gate electrode with an insulating film interposed therebetween.

### CROSS-REFERENCE TO RELATED APPLICATIONS

This non-provisional application claims priority under 35 U.S.C. § 119(a) on Patent Application No. 2022-189398 filed in Japan on Nov. 28, 2022 and Patent Application No. 2023-138878 filed in Japan on Aug. 29, 2023, the entire contents of which are hereby incorporated by reference.

### BACKGROUND

This disclosure relates to a thin-film transistor substrate.

Thin-film transistors (TFTs) including an oxide semiconductor material such as indium-gallium-zinc-oxide (IGZO) are used in display devices including liquid crystal display panels and organic light-emitting diode (OLED) display devices and other kinds of devices. An oxide semiconductor TFT generates small leakage current and therefore, contributes to low power consumption of the device.

### SUMMARY

A thin-film transistor substrate according to an aspect of this disclosure includes a first insulating film, a second insulating film located upper than the first insulating film, a first thin-film transistor, a second thin-film transistor, and a capacitive element. The first thin-film transistor includes a top-gate electrode and a first semiconductor region located above the first insulating film. The second thin-film transistor includes a second semiconductor region located above the second insulating film. The capacitive element includes at least a part of the top-gate electrode and a first low-resistive semiconductor region of the same semiconductor layer that includes the second semiconductor region, the first low-resistive semiconductor region overlapping at least a part of the top-gate electrode with an insulating film interposed therebetween.

It is to be understood that both the foregoing general description and the following detailed description are exemplary and explanatory and are not restrictive of this disclosure.

### BRIEF DESCRIPTION OF THE DRAWINGS

FIG. 1 illustrates a configuration example of an OLED display device related to an embodiment of this specification.

FIG. 2 illustrates a configuration example of a pixel circuit and control signals therefor related to an embodiment of this specification.

FIG. 3 illustrates some elements extracted from the pixel circuit of FIG. 2.

FIG. 4A is a cross-sectional diagram schematically illustrating a device structure of the circuit elements shown in FIG. 3.

FIG. 4B is a cross-sectional diagram schematically illustrating another device structure of the circuit elements shown in FIG. 3.

FIG. 5 is a plan diagram illustrating some elements shown in FIG. 4A.

FIG. 6 illustrates some elements extracted from the pixel circuit of FIG. 2.

FIG. 7A is a cross-sectional diagram schematically illustrating a device structure of the circuit elements shown in FIG. 6.

FIG. 7B is a cross-sectional diagram schematically illustrating another device structure of the circuit elements shown in FIG. 6.

FIG. 8 is a plan diagram illustrating some elements shown in FIG. 7A.

FIG. 9 illustrates another configuration example of a thin-film transistor circuit.

FIG. 10 is a plan diagram schematically illustrating a configuration of transistors and a bootstrap capacitive element in FIG. 9.

FIG. 11 illustrates still another configuration example of a thin-film transistor circuit.

FIG. 12 is a cross-sectional diagram schematically illustrating a device structure of the circuit elements shown in FIG. 11.

FIG. 13 is a plan diagram illustrating some elements shown in FIG. 12.

### EMBODIMENTS

Hereinafter, embodiments of this disclosure will be described with reference to the accompanying drawings. It should be noted that the embodiments are merely examples to implement this disclosure and are not to limit the technical scope of this disclosure. Elements common to the drawings are denoted by the same reference signs. Variations of a common element are denoted by the same reference signs. Some elements in the drawings are exaggerated in size or shape for clear understanding of description.

Hereinafter, configurations of a thin-film transistor substrate (TFT substrate) of this disclosure are described. The TFT substrate in an embodiment of this specification is applicable to various devices such as sensor devices and display devices.

An embodiment of this specification uses a low-resistive semiconductor region of the same layer including the semiconductor region of a TFT as an electrode of another circuit element. An embodiment of this specification uses such a low-resistive semiconductor region as an electrode of a capacitive element. This configuration enables efficient structure and manufacture of a thin-film transistor substrate. The semiconductor region of a TFT and the low-resistive semiconductor region can be an oxide semiconductor region and a low-resistive oxide semiconductor region, respectively.

The semiconductor region of a TFT includes source/drain regions and a channel region therebetween. The source/drain regions are in contact with the channel region in an in-plane direction. The channel region has a higher resistance than the source/drain regions. Each source/drain region is a low-resistive region that adjoins the channel region within the semiconductor region. The term “source/drain region” is a generic term of a source region or a drain region. A source/drain region can become a source region or a drain region depending on the direction of the flow of carriers in the channel region. In a configuration where a source/drain region is shared by two TFTs, the source/drain region can be the source region of one TFT and the drain region of the other TFT.

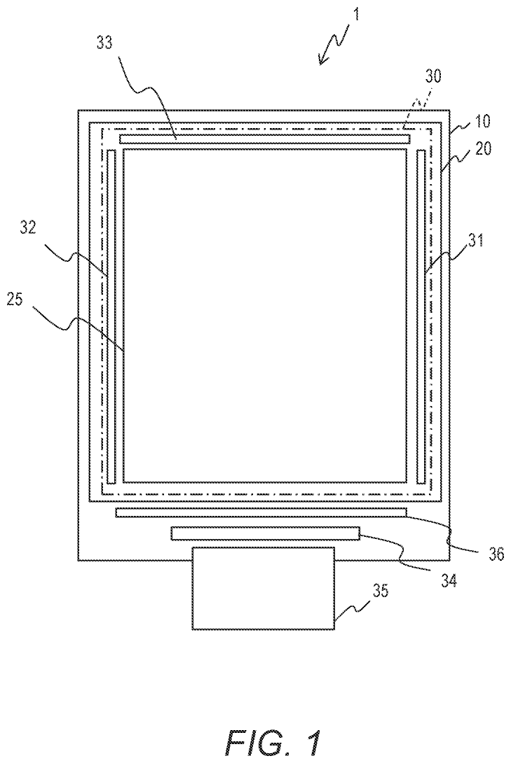

FIG. 1 illustrates a configuration example of an organic light-emitting diode (OLED) display device 1 related to an embodiment of this specification. The OLED display device 1 includes a TFT substrate 10 on which OLED elements and TFTs are fabricated, an encapsulation substrate 20 for encapsulating the OLED elements, and a bond (glass frit sealer) 30 for bonding the TFT substrate with the encapsulation substrate. The space between the TFT substrate 10 and the encapsulation substrate 20 is filled with dry nitrogen and sealed up with the bond 30. The encapsulation substrate 20 and the bond 30 constitute an example of a structural encapsulation unit. Another example of the structural encapsulation unit can have a thin film encapsulation (TFE) structure.

In the periphery outside a display region 25 of the TFT substrate 10, scanning drivers 31 and 32, a protection circuit 33, a driver IC 34, and a demultiplexer 36 are provided. The scanning drivers 31 and 32 and the protection circuit 33 are peripheral circuits fabricated on the TFT substrate. The number of peripheral circuits can be different depending on the design. The driver IC 34 can be connected to the external devices via flexible printed circuits (FPC) 35.

For example, the scanning driver 31 drives scanning lines on the TFT substrate 10. The scanning driver 32 drives control lines to control the emission periods of pixels and to supply a reference potential to the pixels. The protection circuit 33 protects the elements in the pixel circuits from electrostatic discharge. The driver IC 34 provides power and a timing signal (control signal) to the scanning drivers 31 and 32 and further, provides power and a data signal to the demultiplexer 36. The demultiplexer 36 changes the data line to output the data signal from the driver IC 34 d times per scanning period to drive d times as many data lines as output pins of the driver IC 34.

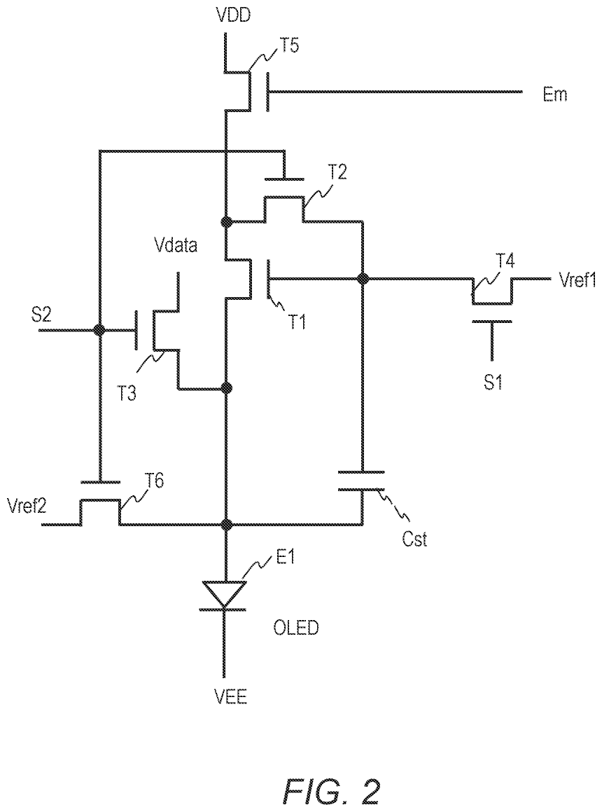

FIG. 2 illustrates a configuration example of a pixel circuit and control signals therefor related to an embodiment of this specification. The pixel circuit includes six transistors (TFTs) T1 to T6 each having a gate, a source, and a drain. All transistors T1 to T6 are n-type oxide semiconductor TFTs. The transistors T2, T3, T4, T5, and T6 are switching transistors.

The transistor T1 is a driving transistor for controlling the amount of electric current to an OLED element E1. The drain of the driving transistor T1 is connected to a power line for transmitting a positive power supply potential VDD via the transistor T5. The driving transistor T1 controls the amount of electric current to be supplied from the power line to the OLED element E1 in accordance with the voltage stored in a storage capacitive element Cst. The storage capacitive element Cst holds the written voltage throughout the period of one frame. The cathode of the OLED element E1 is connected to a power line for transmitting a negative power supply potential VEE from a cathode power supply.

The storage capacitive element Cst is connected between the gate of the driving transistor T1 and the source of the driving transistor T1 or the anode of the OLED element E1. The storage capacitive element Cst stores the voltage between the gate and the source of the driving transistor T1.

The transistor T5 is an emission control switching transistor for controlling ON/OFF of supply of driving current to the OLED element E1 and the resulting light emission of the OLED element E1. The source of the transistor T5 is connected to the drain of the driving transistor T1. The gate of the transistor T5 is connected to a control signal line for transmitting an emission control signal Em and the transistor T5 is controlled by the emission control signal Em from the scanning driver 32.

The transistor T6 works to supply a reference potential Vref2 to the anode of the OLED element E1. One of the source/drain regions of the transistor T6 is connected to a power line for transmitting the reference potential Vref2 and the other source/drain region is connected to the anode of the OLED element E1. The reference potential Vref2 can be equal to the cathode power supply potential VEE.

The gate of the transistor T6 is connected to a control signal line for transmitting a selection signal S2 and the transistor T6 is controlled by the selection signal S2. When the transistor T6 is turned ON by the selection signal S2 from the scanning driver 31, the transistor T6 supplies the reference potential Vref2 to the anode of the OLED element E1.

The transistor T2 is a switching transistor for writing a voltage for applying threshold calibration (threshold compensation) to the driving transistor T1 to the storage capacitive element Cst. The source and the drain of the transistor T2 connect the gate and the drain of the driving transistor T1. Accordingly, when the transistor T2 is ON, the driving transistor T1 is diode connected.

The transistor T4 is used to write a voltage for applying threshold compensation to the driving transistor T1 to the storage capacitive element Cst. The transistor T4 controls whether to supply a reference potential Vref1 to the storage capacitive element Cst. One of the source/drain regions of the transistor T4 is connected to a power line for transmitting the reference potential Vref1 and the other source/drain region is connected to the capacitive element Cst and the gate of the transistor T1. The gate of the transistor T4 is connected to a control signal line for transmitting a selection signal S1 and the transistor T4 is controlled by the selection signal S1 input from the scanning driver 31 to its gate.

The transistor T3 is a switching transistor for selecting a pixel circuit to be supplied with a data signal Vdata and writing the data signal Vdata to the storage capacitive element Cst. One of the source/drain regions of the transistor T3 is connected to the storage capacitive element Cst and the anode of the OLED element E1 and the other source/drain region is connected to a data line for transmitting the data signal Vdata.

The gate of the transistor T3 is connected to the control signal line for transmitting the selection signal S2 from the scanning driver 31. The transistors T3, T6, and T2 are controlled by the selection signal S2. For the pixel circuit, the selection signal S2 is a selection signal for controlling supply of the data signal Vdata to the storage capacitive element Cst.

FIG. 2 illustrates merely an example of a pixel circuit; the features of this disclosure are applicable to pixel circuits having other configurations.

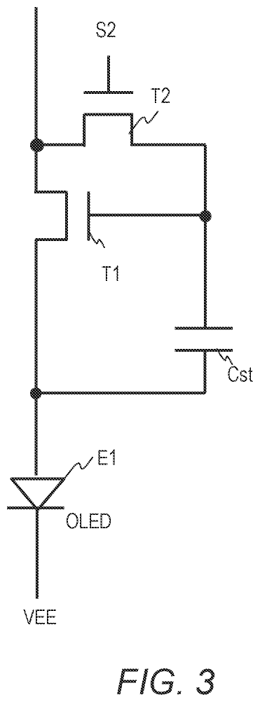

FIG. 3 illustrates some elements extracted from the pixel circuit of FIG. 2. Specifically, FIG. 3 illustrates the driving transistor T1, the switching transistor T2 whose source/drain regions are connected to the drain and the gate of the driving transistor T1, the storage capacitive element Cst, and the OLED element E1.

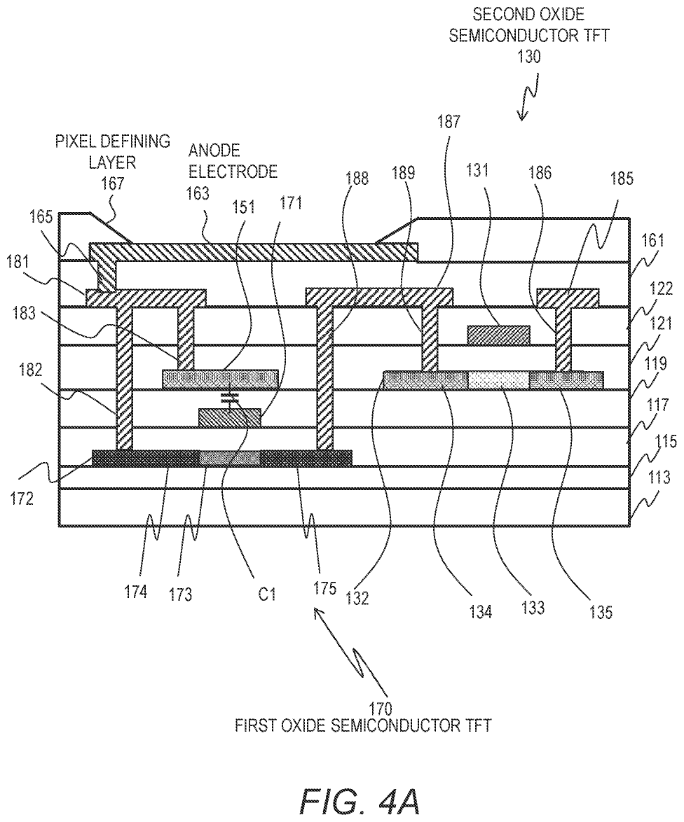

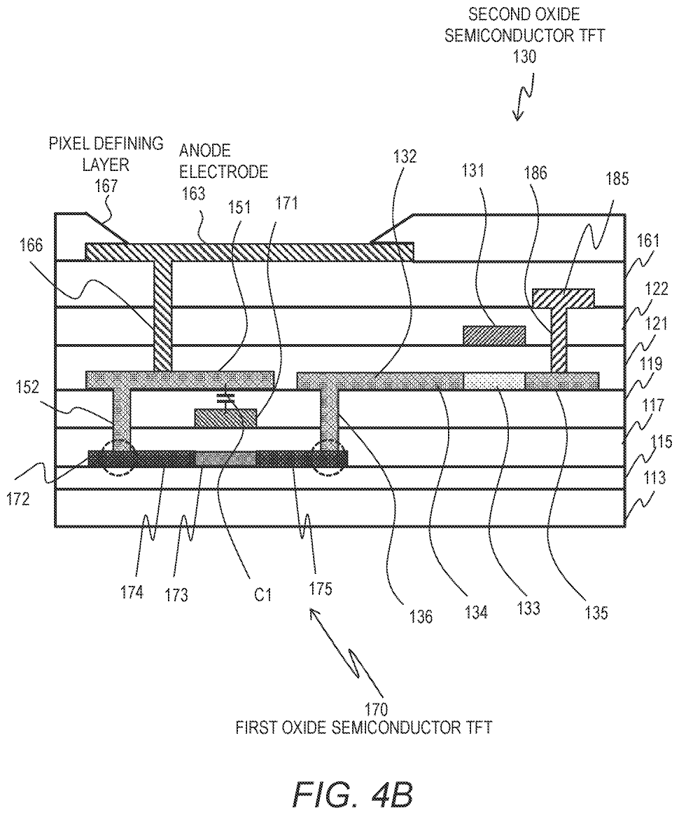

FIG. 4A is a cross-sectional diagram schematically illustrating a device structure of the circuit elements shown in FIG. 3. The first oxide semiconductor TFT 170 corresponds to the driving transistor T1 and the second oxide semiconductor TFT 130 corresponds to the switching transistor T2. The capacitive element C1 corresponds to the storage capacitive element Cst. The anode electrode 163 corresponds to the anode electrode of the OLED element E1. A multilayer organic light-emitting film and a cathode electrode above the anode electrode 163 are omitted in FIG. 4A. The area to determine the capacitance of the capacitive element C1 can be a half or more of the area of the top-gate electrode 171 of the first oxide semiconductor TFT 170. The capacitive element C1 can be structured so that the top-gate electrode 171 overlaps a low-resistive oxide semiconductor region 151 in a half or more of its region when viewed planarly.

The first oxide semiconductor TFT 170 and the second oxide semiconductor TFT 130 are fabricated on a flexible or inflexible insulating substrate 113 made of resin or glass. In the following description, the layer closer to the insulating substrate 113 between two layers layered in contact with each other (two layers having an interface) is a lower layer and the layer farther from the insulating substrate 113 is an upper layer.

The oxide semiconductor region (first oxide semiconductor region) 172 of the first oxide semiconductor TFT 170 and the oxide semiconductor region (second oxide semiconductor region) 132 of the second oxide semiconductor TFT 130 have different or same characteristics. In this example, the mobility of the first oxide semiconductor region is lower than the mobility of the second oxide semiconductor region and the bandgap of the second oxide semiconductor region is narrower than the bandgap of the first oxide semiconductor region.

Examples of the oxide semiconductor material that can be used for the first oxide semiconductor region 172 include IGZO, GaZnO, and IGO. Examples of the oxide semiconductor material that can be used for the second oxide semiconductor region 132 include ITZO, IGZTO, In—Zn—Ti—O, and In—W—Z—O. The first oxide semiconductor region 172 and the second oxide semiconductor region 132 can be made of materials composed of the same kinds of elements (for example, IGZO) but having different composition distributions. The first oxide semiconductor region 172 and the second oxide semiconductor region 132 can be made of the same material composed of the same kinds of elements and having the same composition distribution.

The first oxide semiconductor region 172 is provided above and in contact with an insulating film 115. The second oxide semiconductor region 132 is provided above and in contact with another insulating film 119. The insulating film 119 is located upper than the insulating film 115. The first oxide semiconductor region 172 is located lower than the second oxide semiconductor region 132. Each of the first oxide semiconductor region 172 and the second oxide semiconductor region 132 is a part or all of one semiconductor film.

In the configuration example in FIG. 4A, the entire first oxide semiconductor region 172 is provided above and in contact with the insulating film 115 and the entire second oxide semiconductor region 132 is provided above and in contact with the insulating film 119.

An insulating film 117 is interposed between the insulating film 115 and the insulating film 119. The insulating film 117 is provided above and in contact with the oxide semiconductor region 172 and the insulating film 115. The insulating film 117 covers at least a part of the oxide semiconductor region 172 and at least a part of the insulating film 115. The insulating film 119 is partially in contact with the insulating film 117.

The first oxide semiconductor TFT 170 includes the first oxide semiconductor region 172, a top-gate electrode 171 located upper than the first oxide semiconductor region 172, and a gate insulating film located between the top-gate electrode 171 and the first oxide semiconductor region 172 in the layering direction. The gate insulating film is a part of the insulating film 117. The gate insulating film is in contact with and interposed between the undersurface of the top-gate electrode 171 and the top face of the oxide semiconductor region 172. The top-gate electrode 171 is covered with the insulating film 119. A part of the insulating film 119 is in contact with the top face of the top-gate electrode 171. The first oxide semiconductor TFT 170 can include a bottom-gate electrode in addition to the top-gate electrode 171.

The first oxide semiconductor region 172 includes two source/drain regions 174 and 175 and a channel region 173 between the source/drain regions 174 and 175. The source/drain regions 174 and 175 are included in different low-resistive regions and the channel region 173 is included in a highly-resistive region. The channel region 173 is covered with the top-gate electrode 171 with the gate insulating film interposed therebetween in the layering direction.

The second oxide semiconductor TFT 130 includes the second oxide semiconductor region 132, a top-gate electrode 131 located upper than the second oxide semiconductor region 132, and a gate insulating film located between the top-gate electrode 131 and the second oxide semiconductor region 132 in the layering direction. The gate insulating film is a part of an insulating film 121. The gate insulating film is in contact with and interposed between the undersurface of the top-gate electrode 131 and the top face of the second oxide semiconductor region 132. The second oxide semiconductor TFT 130 can include a bottom-gate electrode in place of or in addition to the top-gate electrode 131.

The insulating film 121 is located upper than the insulating film 119 and another insulating film 122 is provided upper than the insulating film 121. The insulating film 121 is located between the insulating film 119 and the insulating film 122. The insulating film 121 is provided above and in contact with the oxide semiconductor region 132 and the insulating film 119. The insulating film 121 covers at least a part of the second oxide semiconductor region 132 and at least a part of the insulating film 119. The insulating film 121 is partially in contact with the insulating film 119.

The top-gate electrode 131 is covered with the insulating film 122. A part of the insulating film 122 is in contact with the top-gate electrode 131 and another part is in contact with the insulating film 121. A source/drain electrode 185 made of a conductor includes a contact region 186 extending through the insulating films 122 and 121 and being in contact with the top face of a source/drain region 135.

The second oxide semiconductor region 132 includes two source/drain regions 134 and 135 and a channel region 133 between the source/drain regions 134 and 135. The source/drain regions 134 and 135 are included in different low-resistive regions and the channel region 133 is included in a highly-resistive region. The channel region 133 is covered with the top-gate electrode 131 in the layering direction with the gate insulating film interposed therebetween.

An interconnection region 187 made of a conductor interconnects the source/drain region 175 of the first oxide semiconductor TFT and the source/drain region 134 of the second oxide semiconductor TFT. The interconnection region 187 includes a contact region 188 extending through the insulating films 122, 121, 119, and 117 and being in contact with the top face of the source/drain region 175. The interconnection region 187 further includes a contact region 189 extending through the insulating film 122 and 121 and being in contact with the top face of the source/drain region 134. A part of the interconnection region 187 including the contact region 188 corresponds to a source/drain electrode of the first oxide semiconductor TFT 170. A part of the interconnection region 187 including the contact region 189 corresponds to a source/drain electrode of the second oxide semiconductor TFT 130.

The capacitive element C1 is configured between a low-resistive oxide semiconductor region 151 and the top-gate electrode 171 of the first oxide semiconductor TFT 170. The low-resistive oxide semiconductor region 151 is located upper than the top-gate electrode 171 with a part of the insulating film 119 interposed therebetween. The insulating film 119 is in contact with the undersurface of the low-resistive oxide semiconductor region 151 and the top face of the top-gate electrode 171.

The low-resistive oxide semiconductor region 151 is included in the same oxide semiconductor layer as the second oxide semiconductor region 132 and separate from the second oxide semiconductor region 132. This configuration enables efficient manufacture. The low-resistive oxide semiconductor region 151 is made of the same oxide semiconductor material as the second oxide semiconductor region 132. At least a part of the low-resistive oxide semiconductor region 151 is in contact with the insulating film 119; for example, the entire region is in contact with the insulating film 119. In this example, the low-resistive oxide semiconductor region 151 is provided above the insulating film 119 and is physically separate from the second oxide semiconductor region 132.

The low-resistive oxide semiconductor region 151 can be produced together with the source/drain regions (low-resistive oxide semiconductor regions) 134 and 135. For example, the source/drain regions 134, 135 and the low-resistive oxide semiconductor region 151 can be produced by patterning a highly-resistive oxide semiconductor layer and reducing the resistance of the pertinent regions by exposing the pertinent regions to plasma or implanting impurity ions into the pertinent regions. Examples of the plasma include helium plasma, argon plasma, and hydrogen plasma. Examples of the impurity ions include boron ions and phosphorous ions. In these cases, the low-resistive oxide semiconductor region 151 contains at least one of the impurity elements of helium, argon, hydrogen, boron, and phosphorus, in addition to the constituent elements of the oxide semiconductor (in the case of IGZO, In, Ga, Zn, and O).

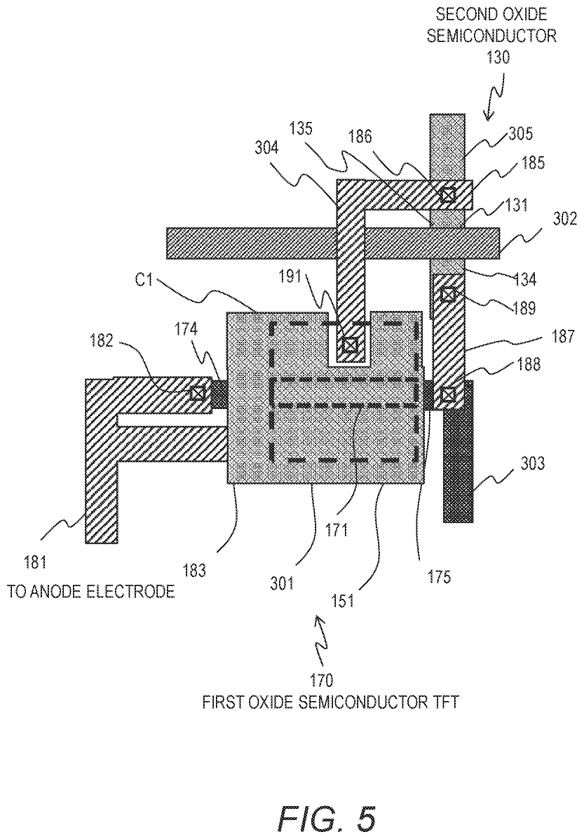

As described with reference to the circuit diagram of FIG. 2 or 3, one end of the storage capacitive element Cst is connected to the gate of the transistor T1 and a source/drain of the transistor T2 and their potentials are equal. Although not shown in FIG. 4A, the top-gate electrode 171 of the first oxide semiconductor TFT 170 is physically connected to the source/drain region 135 of the second oxide semiconductor TFT 130, which will be described later with reference to FIG. 5.

As described with reference to the circuit diagram of FIG. 2 or 3, the other end of the storage capacitive element Cst is connected to the source of the driving transistor T1. An interconnection region 181 made of a conductor interconnects the low-resistive oxide semiconductor region 151 and the source/drain region 174 of the first oxide semiconductor TFT 170. The interconnection region 181 includes a contact region 182 extending through the insulating films 122, 121, 119, and 117 and being in contact with the top face of the source/drain region 174. The interconnection region 181 further includes a contact region 183 extending through the insulating films 122 and 121 and being in contact with the top face of the low-resistive oxide semiconductor region 151. A part of the interconnection region 181 including the contact region 182 corresponds to a source/drain electrode of the first oxide semiconductor TFT 170.

A planarization film 161 is provided above the interconnection regions 181 and 187, the source/drain electrode 185, and the insulating film 122. The planarization film 161 can be made of a coatable organic material having a good flatness, such as acrylic or polyimide. The anode electrode 163 is provided above and in contact with the planarization film 161.

The anode electrode 163 is connected to the interconnection region 181 via a contact region 165 extending through the planarization film 161. The anode electrode 163 can be a layered film of ITO and a metal having high reflectivity such as aluminum or silver.

A pixel defining layer 167 is provided above the anode electrode 163. The pixel defining layer 167 can be an organic film made of acrylic or polyimide. A part of the anode electrode 163 is exposed within an opening of the pixel defining layer 167; a multilayer organic film and a cathode electrode, which are not shown in FIG. 4A, are layered above the anode electrode 163. The organic film emits light in response to electric current supplied thereto. The cathode electrode of each pixel is a part of one conductive film and is supplied with a common cathode power supply potential. The cathode electrode can be made of ITO.

The insulating substrate 113 can be made of glass or flexible or rigid resin. An example of the resin is polyimide. The insulating film 115 can be made of silicon nitride (SiNx), silicon oxide (SiOx), or layered films of these.

The oxide semiconductor region 172 can be made of IGZO, GaZnO, or IGO. The low-resistive regions can be produced by implanting impurity ions (for example, boron ions) to the pertinent regions of an oxide semiconductor film across the insulating film 117, using the top-gate electrode 171 as a mask (self-alignment). This method attains a smaller ΔL, which is advantageous to downsize a TFT. A low-resistive region of an oxide semiconductor film is flatter and has less grain boundaries than a low-resistive region of a polysilicon film; accordingly, it provides an oxide semiconductor TFT with better characteristics. The low-resistive regions can also be produced by exposing the pertinent regions to He plasma.

The insulating film 117, a part of which corresponds to the gate insulating film of the first oxide semiconductor TFT 170, can be made of silicon nitride, silicon oxide, or layered films of these. The top-gate electrode 171 can be made of any material; for example, it can be a single-layer film of a metal such as Mo, W, Nb, Al, Ta, Cr, or Ti, a layered film of metals selected from these, or an alloy of a metal selected from these. The insulating film 119 covering the top-gate electrode 171 can be made of silicon nitride, silicon oxide, or layered films of these.

The oxide semiconductor region 132 and the low-resistive oxide semiconductor region 151 provided above and in contact with the insulating film 119 can be made of ITZO, IGZTO, In—Zn—Ti—O, or In—W—Z—O. The source/drain regions 134 and 135 of the oxide semiconductor region 132 can be produced by implanting impurity ions (for example, boron ions) to the pertinent regions of an oxide semiconductor film across the insulating film 121, using the top-gate electrode 131 as a mask (self-alignment). The low-resistive oxide semiconductor region 151 can be produced together with the source/drain regions 134 and 135. This method attains a smaller ΔL, which is advantageous to downsize a TFT. The low-resistive regions can also be produced by exposing the pertinent regions to He plasma. A low-resistive region of an oxide semiconductor film is flatter and has less grain boundaries than a low-resistive region of a polysilicon film; accordingly, it provides an oxide semiconductor TFT with better characteristics.

The insulating film 121, a part of which corresponds to the gate insulating film of the second oxide semiconductor TFT 130, can be made of silicon nitride, silicon oxide, or layered films of these. The top-gate electrode 131 can be made of any material; for example, it can be a single-layer film of a metal such as Mo, W, Nb, Al, Ta, Cr, or Ti, a layered film of metals selected from these, or an alloy of a metal selected from these. The insulating film 122 covering the top-gate electrode 131 can be made of silicon nitride, silicon oxide, or layered films of these.

The conductor regions 181, 187, and 185 can be produced together using the same material. The conductor regions 181, 187, and 185 can have a multilayer structure of Ti/Al/Ti or Mo/Al/Mo. The conductor regions 181, 187, and 185 can have a single-layer structure or made of metal materials different from the aforementioned metal materials.

FIG. 5 is a plan diagram illustrating some elements shown in FIG. 4A. The top-gate electrode 171 of the first oxide semiconductor TFT 170 is surrounded by a dashed line and it is a part of a conductor film 301 surrounded by a similar dashed line. The top-gate electrode 171 is the part covering the channel region 173 (not shown in FIG. 5). The conductor film 301 and the low-resistive oxide semiconductor region 151 sandwich the insulating film 119 shown in FIG. 4A to structure the capacitive element C1.

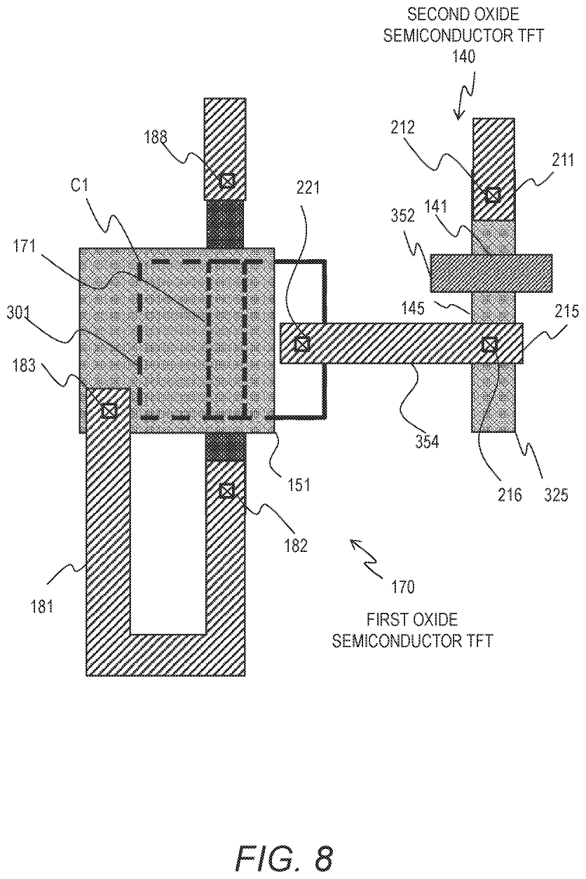

In the planar view of FIG. 5, the entire conductor film 301 is covered with the low-resistive oxide semiconductor region 151. The conductor film 301 can extend to the outside of the low-resistive oxide semiconductor region 151. In the planar view of FIG. 5, the entire top-gate electrode 171 is covered with the low-resistive oxide semiconductor region 151. In another example, the top-gate electrode 171 can face the low-resistive oxide semiconductor region 151 only in a part. These points are applicable to the configuration of FIG. 8, which will be described later.

The conductor film 301 is connected to the source/drain region 135 of the second oxide semiconductor TFT 130 via an interconnection region 304. The interconnection region 304 includes the source/drain electrode 185 and the contact region 186 and further, a contact region 191. The contact region 191 extends through the insulating films 122, 121, and 119. The gap between the inner wall of an indentation of the low-resistive oxide semiconductor region 151 and the contact region 191 is filled with the insulating film 121.

The part of the conductor film 302 covering the channel region 133 of the second oxide semiconductor TFT 130 corresponds to the top-gate electrode 131. A part of the low-resistive oxide semiconductor region 303 corresponds to the source/drain region 175 of the first oxide semiconductor TFT 170. A part of the low-resistive oxide semiconductor region 305 corresponds to the source/drain region 135 of the second oxide semiconductor TFT 130. As described with reference to FIG. 4A, the source/drain regions 134 and 175 are connected via the interconnection region 187 including the contact regions 188 and 189.

FIG. 4A provides a configuration including an interconnection region 187 made of a conductor. Unlike this configuration, the source/drain region 175 of the first oxide semiconductor TFT 170 and the source/drain region 134 of the second oxide semiconductor TFT 130 can be connected via a contact region 136 as illustrated in FIG. 4B, not using the interconnection region 187 of a conductor.

The contact region 136 is included in a low-resistive region of the second oxide semiconductor region 132 of the second oxide semiconductor TFT 130. The source/drain region 134 and the contact region 136 is included in the low-resistive region adjoining the channel region 133. The contact region 136 can be regarded as a part of the source/drain region 134.

The contact region 136 is directly connected to the source/drain region 175 of the first oxide semiconductor TFT 170 by extending through the insulating films 119 and 117 and being in contact with the top face of the source/drain region 175. The source/drain region 175 is included in a low-resistive region adjoining the channel region 173 of the first oxide semiconductor TFT 170. The part of the source/drain region 175 in contact with the contact region 136 is doped with impurity ions twice. The first time is when impurity ions are implanted using the gate electrode 171 as a mask and the second time is when impurity ions are implanted using the gate electrode 131 as a mask.

Accordingly, the part (region) of the source/drain region 175 in contact with the contact region 136 has a higher impurity concentration than the other part that is not in contact with the contact region 136. Since the part in contact with the contact region 136 is reduced in resistance by being doped with high concentration impurity ions as described above, it has a low contact resistance.

The same modification is applicable to the interconnection region 181 made of a conductor. Specifically, the source/drain region 174 of the first oxide semiconductor TFT 170 and the low-resistive oxide semiconductor region 151 can be connected via a contact region 152, not using the interconnection region 181 of a conductor.

The contact region 152 is included in the low-resistive oxide semiconductor region 151. The contact region 152 is directly connected to the source/drain region 174 of the first oxide semiconductor TFT 170 by extending through the insulating films 119 and 117 and being in contact with the top face of the source/drain region 174. The source/drain region 174 is included in a low-resistive region adjoining the channel region 173 of the first oxide semiconductor TFT 170. The part of the source/drain region 174 in contact with the contact region 152 is doped with impurity ions twice. The first time is when impurity ions are implanted using the gate electrode 171 as a mask and the second time is when impurity ions are implanted using the gate electrode 131 as a mask.

Accordingly, the part (region) of the source/drain region 174 in contact with the contact region 152 has a higher impurity concentration than the other part that is not in contact with the contact region 152. Since the part in contact with the contact region 152 is reduced in resistance by being doped with high concentration impurity ions as described above, it has a low contact resistance.

The anode electrode 163 includes a contact region 166 extending through the planarization film 161 and the insulating films 122 and 121. The contact region 166 is directly connected to the low-resistive oxide semiconductor region 151 by being in contact with the top face of the low-resistive oxide semiconductor region 151. The anode electrode 163 and the low-resistive oxide semiconductor region 151 are connected via the contact region 166.

The anode electrode 163 is directly connected to the low-resistive oxide semiconductor region 151. Since the anode electrode 163 is made of layered films of ITO and a highly reflective metal such as aluminum or silver, the direct connection region has a structure such that ITO is in contact with the low-resistive oxide semiconductor region 151. Since ITO and the low-resistive oxide semiconductor have analogous physical properties, good contact characteristics are attained.

In FIG. 4B, the source/drain electrode 185 and the anode electrode 163 are included in two different layers of different metals. In another example, the anode electrode can be included in the same layer and made of the same metal as the source/drain electrode. In this case, reduction in process steps is available, contributing to lower cost. Furthermore, the configuration of FIG. 4B includes fewer contact holes than the configuration of FIG. 4A, contributing to space-saving. This is advantageous for an OLED panel to have higher resolution.

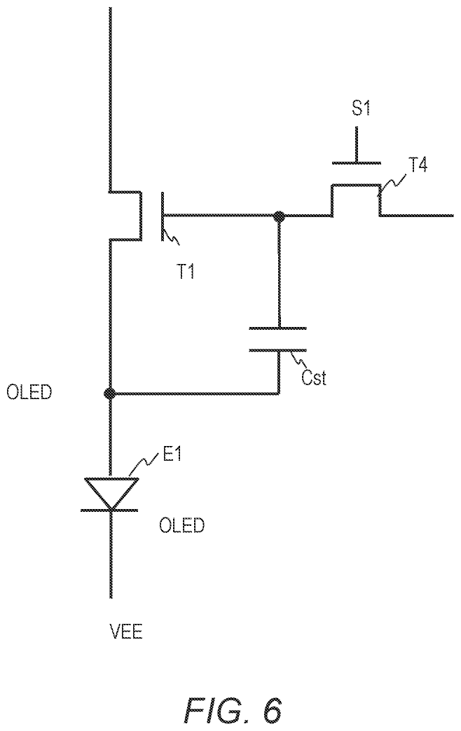

FIG. 6 illustrates some elements extracted from the pixel circuit of FIG. 2. Specifically, FIG. 6 illustrates the driving transistor T1, the switching transistor T4 whose source/drain region is connected to the gate of the driving transistor T1, the storage capacitive element Cst, and the OLED element E1. The difference from the configuration of FIG. 3 is that a source/drain of the switching transistor is not connected to a source/drain of the driving transistor T1.

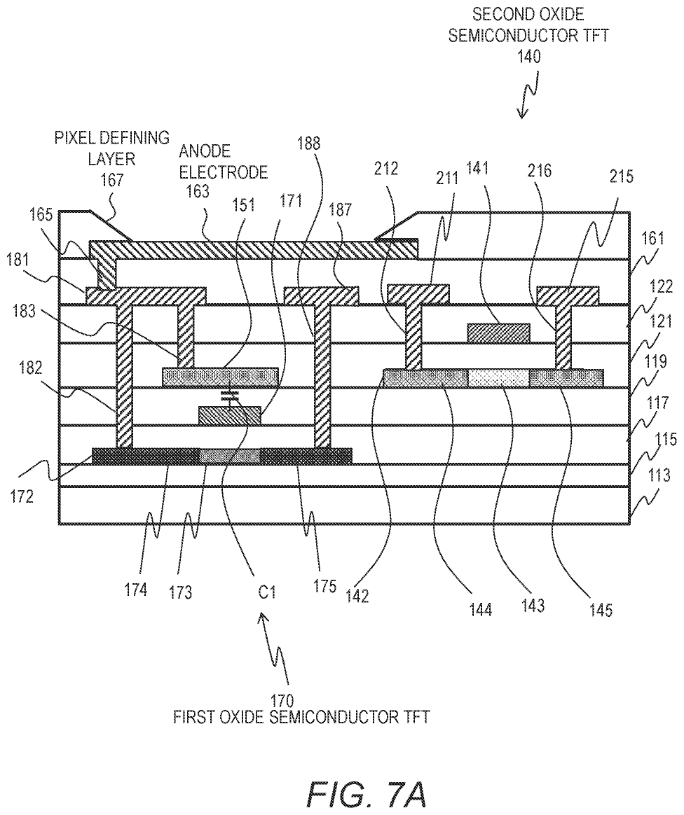

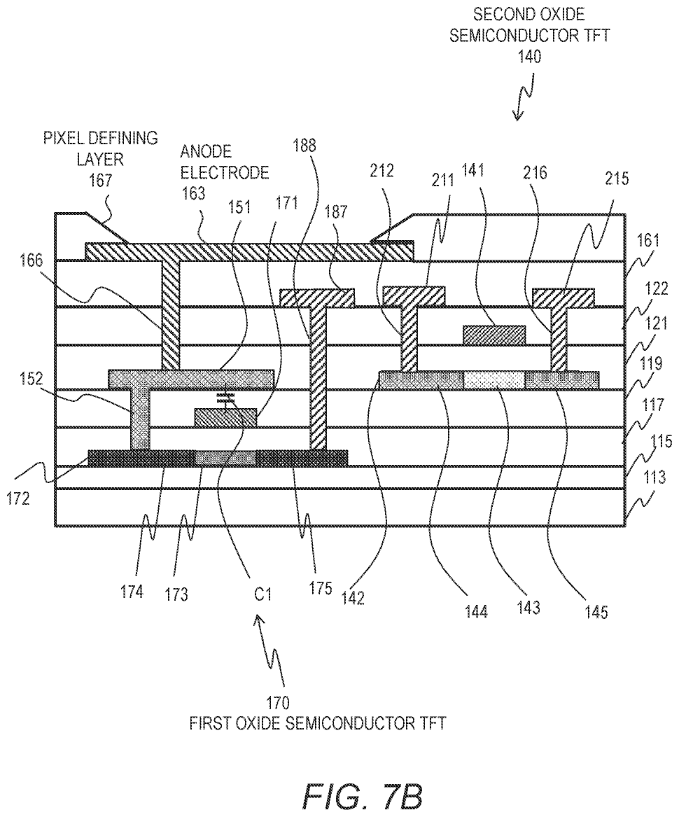

FIG. 7A is a cross-sectional diagram schematically illustrating a device structure of the circuit elements shown in FIG. 6. The first oxide semiconductor TFT 170 corresponds to the driving transistor T1 and the second oxide semiconductor TFT 140 corresponds to the switching transistor T4. The anode electrode 163 is the anode electrode of the OLED element E1. In the following, differences from the configuration example in FIG. 4A are mainly described.

The second oxide semiconductor TFT 140 includes a top-gate electrode 141 in place of the top-gate electrode 131 of the second oxide semiconductor TFT 130 in FIG. 4A. The second oxide semiconductor TFT 140 further includes a channel region 143 and source/drain regions 144 and 145 in place of the channel region 133 and the source/drain regions 134 and 135, respectively. These are parts of an oxide semiconductor region 142. Furthermore, a source/drain electrode 215 has replaced the source/drain electrode 185 and a source/drain electrode 211 has replaced the interconnection region 187. The second oxide semiconductor TFT 140 can include a bottom-gate electrode in place of or in addition to the top-gate electrode 141.

The source/drain electrode 215 includes a contact region 216 extending through the insulating films 122 and 121. The contact region 216 is in contact with the top face of the source/drain region 145. The source/drain electrode 211 includes a contact region 212 extending through the insulating films 122 and 121. The contact region 212 is in contact with the top face of the source/drain region 144. The materials and manufacturing method of the elements of the second oxide semiconductor TFT 130 are applicable to the corresponding elements of the second oxide semiconductor 140.

For example, the low-resistive oxide semiconductor region 151 is included in the same oxide semiconductor layer as the oxide semiconductor region 142. The low-resistive oxide semiconductor region 151 can be made of the same material as the source/drain regions (low-resistive oxide semiconductor regions) 144 and 145. These regions can be produced together by the same film formation, patterning, and resistance reduction process.

FIG. 8 is a plan diagram illustrating some elements shown in FIG. 7A. The top-gate electrode 171 of the first oxide semiconductor TFT 170 is surrounded by a dashed line and it is a part of a conductor film 301 surrounded by a similar dashed line. The top-gate electrode 171 is the part covering the channel region 173 (not shown in FIG. 8). The conductor film 301 and the low-resistive oxide semiconductor region 151 sandwich the insulating film 119 shown in FIG. 7A to structure the capacitive element C1.

The conductor film 301 is connected to the source/drain region 145 of the second oxide semiconductor TFT 140 via an interconnection region 354. The interconnection region 354 includes the source/drain electrode 215 and the contact region 216 and further, a contact region 221. The contact region 221 extends through the insulating films 122, 121, and 119. The gap between the end face of the low-resistive oxide semiconductor region 151 and the contact region 221 is filled with the insulating film 121.

The part of the conductor film 352 covering the channel region 143 of the second oxide semiconductor TFT 140 corresponds to the top-gate electrode 141. A part of the low-resistive oxide semiconductor region 325 corresponds to the source/drain region 145 of the second oxide semiconductor TFT 140.

FIG. 7A provides a configuration including an interconnection region 181 made of a conductor. Unlike this configuration, the source/drain region 174 of the first oxide semiconductor TFT 170 and the low-resistive oxide semiconductor region 151 can be connected via a contact region 152 as illustrated in FIG. 7B, not using the interconnection region 181 of a conductor. The configuration and effects of the contact region 152 in FIG. 7B are as described with reference to FIG. 4B.

The anode electrode 163 includes a contact region 166 extending through the planarization film 161 and the insulating films 122 and 121. The contact region 166 is directly connected to the low-resistive oxide semiconductor region 151 by being in contact with the top face of the low-resistive oxide semiconductor region 151. The anode electrode 163 and the low-resistive oxide semiconductor region 151 are connected via the contact region 166. The configuration and effects of the contact region 166 are as described with reference to FIG. 4B.

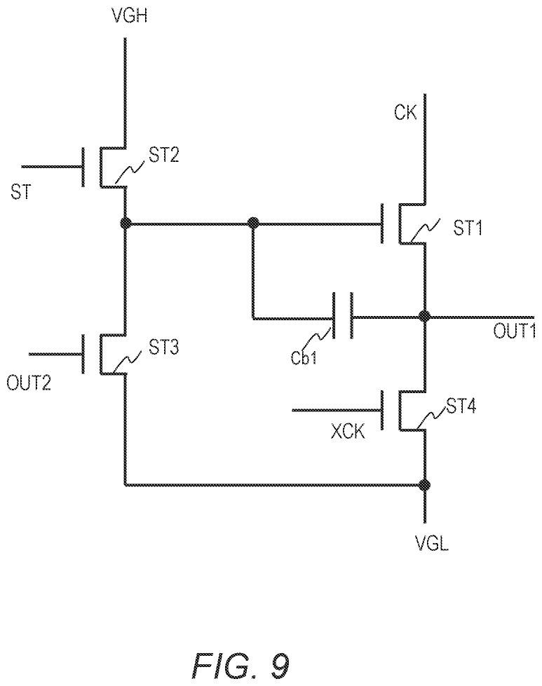

FIG. 9 illustrates another configuration example of a thin-film transistor circuit. FIG. 9 illustrates a part of a circuit included in one stage of a shift register. The shift register can be incorporated into the scanning driver 31 or 32. The shift register includes n-type transistors ST1 to ST4 and a capacitive element Cb1. The potential VGH is a high power-supply potential and the potential VGL is a low power-supply potential. The signal ST is a start pulse or an output from the previous stage. The signal OUT1 is an output. The signal OUT2 is a feedback signal from the next stage. The signal CK is a clock signal and the signal XCK is an inverted clock signal.

In the circuit illustrated in FIG. 9, the transistor ST1 is a transistor that mainly receives a negative gate bias. The transistors ST2 to ST4 are transistors that mainly receive a positive gate bias. The capacitive element Cb1 is a bootstrap capacitive element.

The description about transistors and a capacitive element provided with reference to FIG. 7A is applicable to the transistors ST1 and ST2 and the capacitive element Cb1. Specifically, the first oxide semiconductor TFT 170 corresponds to the transistor ST1; the second oxide semiconductor TFT 140 corresponds to the transistor ST2; and the capacitive element C1 corresponds to the bootstrap capacitive element Cb1, although the anode electrode 163 for the OLED element E1 and the pixel defining layer 167 are excluded.

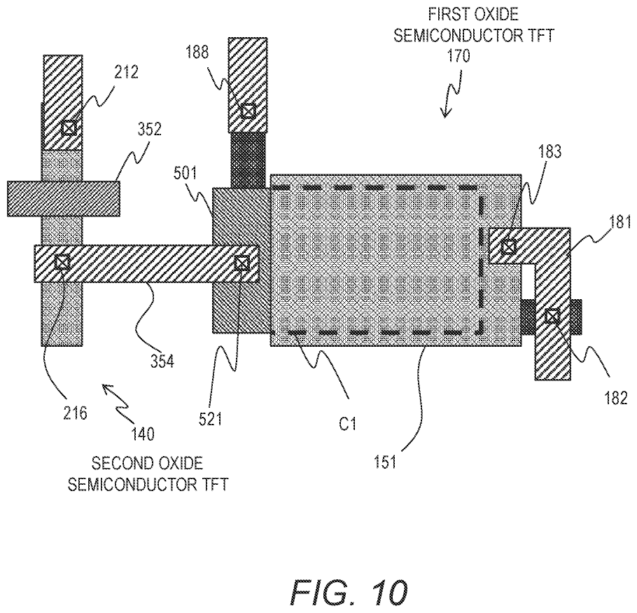

FIG. 10 is a plan diagram schematically illustrating a configuration of the oxide semiconductor TFTs 170 and 140 and the capacitive element C1 illustrated in FIG. 7A corresponding to the transistors ST1 and ST2 and the bootstrap capacitive element Cb1 in FIG. 9. The elements denoted by the same reference signs as those in the configuration example in FIG. 8 are the elements common to FIGS. 10 and 8. The common elements can have different shapes between FIGS. 10 and 8.

The capacitive element C1 corresponding to the bootstrap capacitive element Cb1 is configured between the low-resistive oxide semiconductor region 151 and a part of a conductor film 501 including the top-gate electrode 171 (not shown in FIG. 10) of the first oxide semiconductor TFT 170. The interconnection region 354 is connected to the conductor film 501 via a contact region 521. The contact region 521 is located outside the low-resistive oxide semiconductor region 151 and extends through the insulating films 122, 121, and 119 to be in contact with the top face of the conductor film 501. The entire region of the conductor film 501 can face the low-resistive oxide semiconductor region 151 in the layering direction.

Using the low-resistive oxide semiconductor region 151 of the same oxide semiconductor layer as the second oxide semiconductor region 132 as one of the electrodes of the bootstrap capacitive element Cb1 enables the shift register circuit to have a smaller circuit area.

In the configurations described with reference to FIGS. 2 to 10, the semiconductor regions of the first oxide semiconductor TFT and the second oxide semiconductor TFT can be made of a semiconductor material different from an oxide semiconductor, for example, polysilicon.

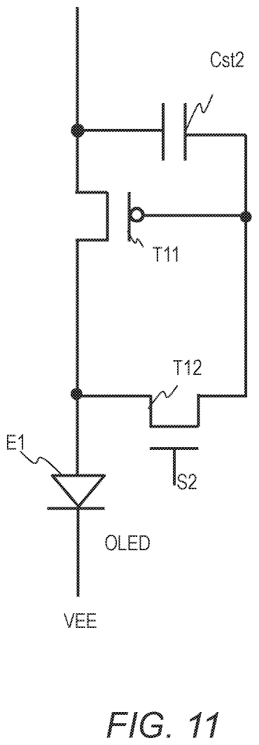

FIG. 11 illustrates still another configuration example of a thin-film transistor circuit. FIG. 11 illustrates some of the elements included in a pixel circuit employing a p-type transistor for the driving transistor. Specifically, FIG. 11 includes a p-type driving transistor T11, an n-type switching transistor T12 connected between the gate and the drain of the driving transistor T11, and a storage capacitive element Cst2 configured between the gate and the source of the driving transistor T11. The overall pixel circuit has a configuration such that the transistors T1 and T2 and the storage capacitive element Cst in the pixel circuit configuration illustrated in FIG. 2 are replaced with the transistors T11 and T12 and the storage capacitive element Cst2, respectively.

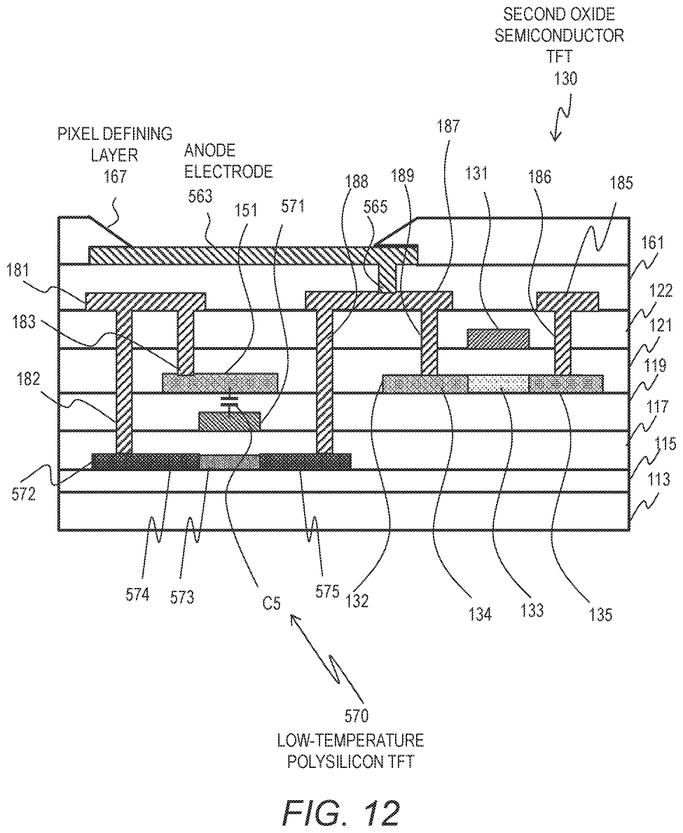

FIG. 12 is a cross-sectional diagram schematically illustrating a device structure of the circuit elements shown in FIG. 11. The polysilicon TFT 570 corresponds to the driving transistor T11 and the second oxide semiconductor TFT 130 corresponds to the switching transistor T12. The capacitive element C5 corresponds to the storage capacitive element Cst2. In the following, differences from the configuration example in FIG. 4A are mainly described.

In the configuration example of FIG. 12, the low-temperature polysilicon TFT 570 has replaced the first oxide semiconductor TFT 170 in the configuration example of FIG. 4A. In addition, the anode electrode 563 has replaced the anode electrode 163. The anode electrode 563 includes a contact region 565 extending through the planarization film 161 and being in contact with the top face of the interconnection region 187.

The low-temperature polysilicon TFT 570 includes a polysilicon region 572, a top-gate electrode 571 located upper than the polysilicon region 572, and a gate insulating film located between the top-gate electrode 571 and the polysilicon region 572 in the layering direction. The gate insulating film is a part of the insulating film 117. The gate insulating film is in contact with and interposed between the undersurface of the top-gate electrode 571 and the top face of the polysilicon region 572. The top-gate electrode 571 is covered with the insulating film 119. A part of the insulating film 119 is in contact with the top face of the top-gate electrode 571. The low-temperature polysilicon TFT 570 can include a bottom-gate electrode in addition to the top-gate electrode 571.

The polysilicon region 572 includes source/drain regions 574 and 575 and a channel region 573 between the source/drain regions 574 and 575. The source/drain regions 574 and 575 have lower resistance than the channel region 573. The source/drain regions 574 and 575 are included in different low-resistive regions and the channel region 573 is included in a highly-resistive region. The channel region 573 is covered with the top-gate electrode 571 with the gate insulating film interposed therebetween in the layering direction.

The capacitive element C5 is configured between the low-resistive oxide semiconductor region 151 and the top-gate electrode 571 of the low-temperature polysilicon TFT 570. The low-resistive oxide semiconductor region 151 is located upper than the top-gate electrode 571 with a part of the insulating film 119 interposed therebetween. The insulating film 119 is in contact with the undersurface of the low-resistive oxide semiconductor region 151 and the top face of the top-gate electrode 571.

As to the material for the top-gate electrode 571, the description about the top-gate electrode 171 is applicable. The polysilicon region 572 is made of polysilicon. A low-temperature polysilicon film can be produced by laser-annealing an amorphous silicon film. The source/drain regions 574 and 575 can be produced by implanting impurity ions to the pertinent regions across the insulating film 117 using the top-gate electrode 571 as a mask.

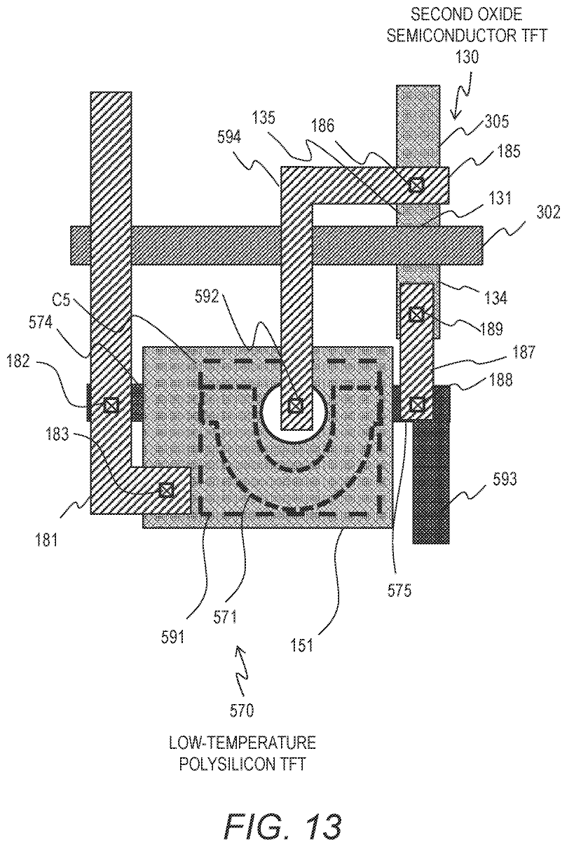

FIG. 13 is a plan diagram illustrating some elements shown in FIG. 12. The top-gate electrode 571 of the low-temperature polysilicon TFT 570 is surrounded by a dashed line and it is a part of a conductor film 591 surrounded by a similar dashed line. The top-gate electrode 571 is the part covering the channel region 573 (not shown in FIG. 13). In the example of FIG. 13, the channel region has a curved shape. The channel regions of oxide semiconductor TFTs and low-temperature polysilicon TFTs can have various shapes, such as a linear shape, a curved shape, and a shape in which a linear part and a curved part are combined.

The conductor film 591 and the low-resistive oxide semiconductor region 151 sandwich the insulating film 119 shown in FIG. 12 to structure the capacitive element C5. The conductor film 591 is connected to the source/drain region 135 of the second oxide semiconductor TFT 130 via an interconnection region 594. In the example of FIG. 13, the entire region of the conductor film 591 faces the low-resistive oxide semiconductor region 151 in the layering direction. In another example, a part of the conductor film 591 or the top-gate electrode 571 can be located outside the low-resistive oxide semiconductor region 151.

The interconnection region 594 includes the source/drain electrode 185 and the contact region 186 and further, a contact region 592. The contact region 592 extends through the insulating films 122, 121, and 119 and is in contact with the top face of the conductor film 591. The space between the inner wall of an opening of the low-resistive oxide semiconductor region 151 and the contact region 592 is filled with the insulating film 121. A part of the conductor film 591 can be located outside the low-resistive oxide semiconductor region 151 without being covered therewith in a planar view. For example, the contact region 592 can be in contact with the conductor film 591 outside the low-resistive oxide semiconductor region 151.

A part of a low-resistive region 593 of a polysilicon film corresponds to the source/drain region 575 of the low-temperature polysilicon TFT 570. As described with reference to FIG. 12, the source/drain regions 134 and 575 are connected via the interconnection region 187 including the contact regions 188 and 189.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A thin-film transistor substrate comprising:
a first insulating film;
a second insulating film located upper than the first insulating film;
a first thin-film transistor;
a second thin-film transistor; and
a capacitive element,
wherein the first thin-film transistor includes a top-gate electrode and a first semiconductor region located above the first insulating film,
wherein the second thin-film transistor includes a second semiconductor region located above the second insulating film,
wherein the capacitive element includes at least a part of the top-gate electrode and a first low-resistive semiconductor region of the same semiconductor layer that includes the second semiconductor region, the first low-resistive semiconductor region overlapping at least a part of the top-gate electrode with an insulating film interposed therebetween.

2. The thin-film transistor substrate according to claim 1, wherein the second semiconductor region and the first low-resistive semiconductor region are made of an oxide semiconductor.

3. The thin-film transistor substrate according to claim 2, wherein the first semiconductor region is made of an oxide semiconductor.

4. The thin-film transistor substrate according to claim 1,
wherein the first semiconductor region is made of polysilicon, and
wherein the second semiconductor region and the first low-resistive semiconductor region are made of an oxide semiconductor.

5. The thin-film transistor substrate according to claim 1, wherein a second low-resistive semiconductor region that adjoins a channel region in the first semiconductor region and a third low-resistive semiconductor region that adjoins a channel region in the second semiconductor region are connected via a contact region.

6. The thin-film transistor substrate according to claim 5,
wherein the contact region is included in the third low-resistive semiconductor region, and
wherein the contact region extends through the second insulating film and is directly connected to the second low-resistive semiconductor region.

7. The thin-film transistor substrate according to claim 1, wherein the top-gate electrode of the first thin-film transistor is connected to a fourth low-resistive semiconductor region that adjoins a channel region in the second semiconductor region.

8. The thin-film transistor substrate according to claim 7,
wherein the first low-resistive semiconductor region further includes a contact region, and
wherein the contact region extends through the second insulating film and is directly connected to a fifth low-resistive semiconductor region that adjoins a channel region in the first semiconductor region.

9. The thin-film transistor substrate according to claim 6, wherein a part of the second low-resistive semiconductor region in contact with the contact region has a higher impurity concentration than a part outside the part in contact with the contact region.

10. The thin-film transistor substrate according to claim 8, wherein a part of the fifth low-resistive semiconductor region in contact with the contact region has a higher impurity concentration than a part outside the part in contact with the contact region.

11. The thin-film transistor substrate according to claim 1, wherein the first low-resistive semiconductor region contains at least one element selected from helium, argon, hydrogen, boron, and phosphorus.
